(19) United States
(12) Patent Application Publication
(10) Pub. No.: US 2007/0194403 A1
(43) Pub. Date: Aug. 23, 2007

(54) Methods for fabricating semiconductor device structures with reduced susceptibility to latch-up and semiconductor device structures formed by the methods

(75) Inventors: Ethan Harrison Cannon, Essex Junction, VT (US); Toshiharu Furukawa, Essex Junction, VT (US); Mark Charles Hakey, Fairfax, VT (US); David Vaclav Horak, Essex Junction, VT (US); Charles William Koburger III, Delmar, NY (US); Jimmy Konstantinos Kontos, Milton, VT (US); Jack Allan Mandelman, Flat Rock, NC (US); William Robert Tonti, Essex Junction, VT (US)

Correspondence Address: WOOD, HERRON & EVANS, L.L.P. (IBM), 2700 CAREW TOWER, 441 VINE STREET, CINCINNATI, OH, 45202, US

(73) Assignee: INTERNATIONAL BUSINESS MACHINES CORPORATION, ARMONK, NY (US)

(21) Appl. No.: 11/360,345

(22) Filed: Feb. 23, 2006

(51) Int. Cl. H01L 21/76

(52) U.S. Cl. 257/506; 438/424

(57) ABSTRACT

Semiconductor methods and device structures for suppressing latch-up in bulk CMOS devices. The method comprises forming a trench in the semiconductor material of the substrate with first sidewalls disposed between a pair of doped wells, also defined in the semiconductor material of the substrate. The method further comprises forming an etch mask in the trench to partially mask the base of the trench, followed by removing the semiconductor material of the substrate exposed across the partially masked base to define narrowed second sidewalls that deepen the trench. The deepened trench is filled with a dielectric material to define a trench isolation region for devices built in the doped wells. The dielectric material filling the deepened extension of the trench enhances latch-up suppression.

### FIELD OF THE INVENTION

The invention relates generally to methods for fabricating semiconductor structures and semiconductor device structures and, in particular, to methods of fabricating bulk complementary metal-oxide-semiconductor device structures with reduced susceptibility to latch-up and bulk complementary metal-oxide-semiconductor device structures formed by the methods.

### BACKGROUND OF THE INVENTION

Complementary metal-oxide-semiconductor (CMOS) technologies integrate P- and N-channel field effect transistors (FETs) to form an integrated circuit on a single semiconductor substrate. A significant issue for bulk CMOS technologies is latch-up, which is precipitated by unwanted transistor action of parasitic bipolar transistors inherently present in bulk CMOS devices. The unwanted parasitic transistor action, which has various triggers, may cause failure of bulk CMOS devices. For space-based applications, latch-up may be induced by the impingement of high energy ionizing radiation and particles (e.g., cosmic rays, neutrons, protons, alpha particles). Because the integrated circuit cannot be easily replaced in space flight systems, the chip failure may prove catastrophic. Hence, designing bulk CMOS devices with a high tolerance to latch-up is an important consideration for circuit operation in the natural space radiation environment, as well as military systems and high reliability commercial applications.

Bulk CMOS device designs may be adjusted to increase latch-up immunity. For example, latch-up immunity may be increased in 0.25 micron device technologies by building bulk CMOS devices on epitaxial substrates (e.g., a p-type epitaxial layer on a highly-doped p-type substrate wafer). Highly-doped substrate wafers provide excellent current sinks for currents that, if unabated, may initiate latch-up. However, epitaxial substrates are expensive to produce and may increase the design complexity of several critical circuits, such as electrostatic discharge (ESD) protective devices.

Guard ring diffusions represent another conventional approach for suppressing latch-up. However, guard ring diffusions are costly because they occupy a significant amount of active area silicon real estate. In addition, although guard ring diffusions collect a majority of the minority carriers in the substrate, a significant fraction may escape collection by traveling underneath and, thereby, bypassing the guard ring diffusion.

Semiconductor-on-insulator (SOI) substrates are recognized by the semiconductor community as generally free of latch-up. However, CMOS devices are expensive to fabricate on an SOI substrate, as compared to a bulk substrate. Furthermore, SOI substrates suffer from various other radiation-induced failure mechanisms aside from latch-up. Another disadvantage is that SOI devices do not generally come with a suite of ASIC books that would enable simple assembly of low-cost designs.

Conventional CMOS devices are susceptible to latch-up generally because of the close proximity of N-channel and P-channel field effect transistors. For example, a typical CMOS device fabricated on a p-type substrate includes opposite conductivity N- and P-wells that are separated by only a short distance and adjoin across a well junction. A P-channel transistor is fabricated in an N-well and, similarly, an N-channel transistor is fabricated in a P-well. This densely-packed bulk CMOS structure inherently forms a parasitic lateral bipolar (PNP) structure and parasitic vertical bipolar (NPN) structure that are prone to the unwanted parasitic transistor action. Latch-up may occur due to regenerative feedback between these PNP and NPN structures.

With reference to FIG. 1, a portion of a standard triple-well bulk CMOS structure 30 (i.e., CMOS inverter) includes a P-channel transistor 10 formed in an N-well 12 of a substrate 11, an N-channel transistor 14 formed in a P-well 16 of the substrate 11 that overlies a buried N-band 18, and a shallow trench isolation (STI) region 20 separating the N-well 12 from the P-well 16. Other STI regions 21 are distributed across the substrate 11. The N-channel transistor 14 includes n-type diffusions representing a source 24 and a drain 25. The P-channel transistor 10 has p-type diffusions representing a source 27 and a drain 28. The N-well 12 is electrically coupled by a contact 19 with the standard power supply voltage (V_{dd}) and the P-well 16 is electrically coupled by a contact 17 to the substrate ground potential. The input of the CMOS structure 30 is connected to a gate 13 of the P-channel transistor 10 and to a gate 15 of the N-channel transistor 14. The output of CMOS structure 30 is connected to the drain 28 of the P-channel transistor 10 and the drain 25 of the N-channel transistor 14. The source 27 of the P-channel transistor 10 is connected to V_{dd} and the source 24 of the N-channel transistor 14 is coupled to ground. Guard ring diffusions 34, 36 encircle the CMOS structure 30.

The n-type diffusions constituting the source 24 and drain 25 of the N-channel transistor 14, the isolated P-well 16, and the underlying N-band 18 constitute the emitter, base, and collector, respectively, of a vertical parasitic NPN structure 22. The p-type diffusions constituting the source 27 and drain 28 of the P-channel transistor 10, the N-well 12, and the isolated P-well 16 constitute the emitter, base, and collector, respectively, of a lateral parasitic PNP structure 26. Because the N-band 18 constituting the collector of the NPN structure 22 and the N-well 12 constituting the base of the PNP structure 26 are shared and the P-well 16 constitutes the base of the NPN structure 22 and also the collector of the PNP structure 26, the parasitic NPN and PNP structures 22, 26 are wired to result in a positive feedback configuration.

A disturbance, such as impinging ionizing radiation, a voltage overshoot on the source 27 of the P-channel transistor 10, or a voltage undershoot on the source 24 of the N-channel transistor 14, may result in the onset of regenerative action. This results in negative differential resistance behavior and, eventually, latch-up of the bulk CMOS structure 30. In latch-up, an extremely low-impedance path is formed between emitters of the vertical parasitic NPN structure 22 and the lateral parasitic PNP structure 26, as a result of the bipolar bases being flooded with carriers. The low-impedance state may precipitate catastrophic failure of the associated portion of the integrated circuit. The latched state may only be exited by removal of, or drastic lowering of, the power supply voltage below the holding voltage. Unfortunately, irreversible damage to the integrated circuit may occur almost instantaneously with the onset of the disturbance so that any reaction to exit the latched state is belated.

What is needed, therefore, is a semiconductor structure and fabrication method for modifying standard bulk CMOS device designs that suppresses latch-up, while being cost effective to integrate into the process flow, and that overcomes the disadvantages of conventional bulk CMOS semiconductor structures and methods of manufacturing such bulk CMOS semiconductor structures.

### SUMMARY OF THE INVENTION

The present invention is generally directed to semiconductor structures and methods that improve latch-up immunity or suppression in standard bulk CMOS device designs, while retaining cost effectiveness for integration into the process flow forming the P-channel and N-channel field effect transistors characteristic of bulk CMOS devices. In accordance with an aspect of the present invention, a method is provided for fabricating a semiconductor structure in a substrate of a semiconductor material. The method comprises forming a trench in the semiconductor material of the substrate with first sidewalls extending between a base of the trench and a top surface of the substrate and forming spacers on the first sidewalls of the trench. The method further comprises etching a portion of the semiconductor material of the substrate exposed between the spacers to deepen the trench by defining a vertical trench extension with second sidewalls that extend from the base into the substrate and that are narrowed relative to the first sidewalls. The utilization of spacers to etch the vertical trench extension eliminates the need for a patterned resist formed by a conventional lithographic process and may also self-align the second sidewalls vertical trench extension with the first sidewalls of the trench.

In accordance with another aspect of the present invention, a method is provided for fabricating a semiconductor structure in a substrate of semiconductor material. The method comprises forming a first trench in the semiconductor material of the substrate with first sidewalls extending between a first base and a top surface of the substrate. The method further comprises forming a second trench in the semiconductor material of the substrate with second sidewalls and extending between a second base and the top surface of the substrate. Spacers of a dielectric material are formed in the first trench that are separated by a gap so as to partially expose the first base. Concurrently with forming the spacers, the second trench is filled by the dielectric material to completely cover the second base. Filling the second trench with dielectric material eliminates the need to mask the second trench during subsequent processes that may modify the first base of the first trench by protecting the second base.

In accordance with yet another aspect of the present invention, a semiconductor structure comprises a substrate of a semiconductor material having a top surface and a trench including a base. The trench, which is defined in the semiconductor material of the substrate, has sidewalls extending from the base toward the top surface. Spacers of a dielectric material are positioned on the sidewalls of the trench and are separated from each other by a gap to partially expose the base. A vertical trench extension has sidewalls extending from the base of the trench away from the top surface into the semiconductor material of the substrate. The sidewalls of the vertical trench extension are substantially aligned with the gap separating the spacers.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic view of a portion of a substrate with a bulk CMOS device constructed in accordance with the prior art.

FIG. 2A is a diagrammatic top view of a portion of a substrate at an initial fabrication stage of a processing method in accordance with an embodiment of the present invention.

FIG. 2B is a cross-sectional view taken generally along lines 2B-2B of FIG. 2A.

FIG. 3A is a diagrammatic top view of the substrate portion at a fabrication stage subsequent to FIG. 2A.

FIG. 3B is a cross-sectional view taken generally along lines 3B-3B of FIG. 3A.

FIG. 4A is a diagrammatic top view of the substrate portion at a fabrication stage subsequent to FIG. 3A.

FIG. 4B is a cross-sectional view taken generally along lines 4B-4B of FIG. 4A.

FIG. 5A is a diagrammatic top view of the substrate portion at a fabrication stage subsequent to FIG. 4A.

FIG. 5B is a cross-sectional view taken generally along lines 5B-5B of FIG. 5A.

FIG. 6A is a diagrammatic top view of the substrate portion at a fabrication stage subsequent to FIG. 5A.

FIG. 6B is a cross-sectional view taken generally along lines 6B-6B of FIG. 6A.

### DETAILED DESCRIPTION

The present invention provides an isolation region that limits the effect of the vertical parasitic NPN structure and the lateral parasitic PNP structure responsible for latch-up in triple-well bulk CMOS devices. The invention is advantageously implemented in the design of bulk CMOS devices where pairs of N-channel and P-channel field effect transistors are formed adjacent to each other in a P-well and an N-well, respectively, and the P-well is isolated from the N-well by a shallow trench isolation (STI) region. Specifically, the latchup immunity of a standard bulk CMOS structures is improved by modifying the geometry of the STI region at the well junction with a narrow dielectric-filled vertical extension region or pigtail. The geometry modification afforded by the pigtail is accomplished without the assistance of a patterned resist mask formed by a conventional lithographic process and is self-aligned relative to the wider and shallower STI region. The present invention will now be described in greater detail by referring to the drawings that accompany the present application.

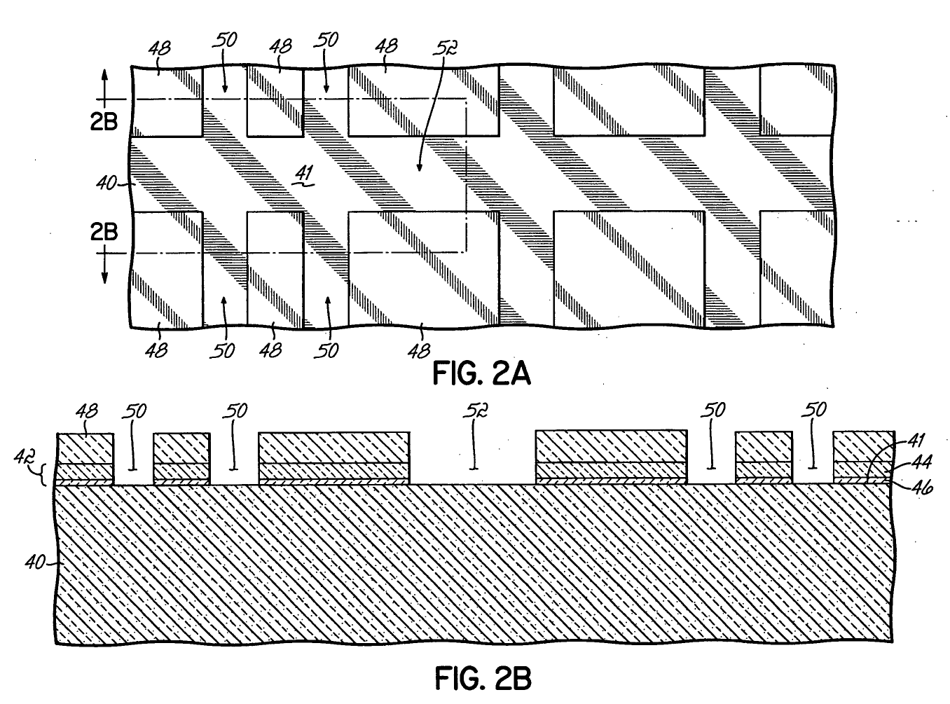

With reference to FIGS. 2A,B, a bulk substrate 40 of a monocrystalline semiconductor material is obtained from, for example, a commercial substrate supplier. Substrate 40 may include a low-defect epitaxial layer for device fabrication that is grown on a much thicker monocrystalline or single crystal wafer by an epitaxial growth process, such as chemical vapor deposition (CVD) using a silicon source gas (e.g., silane). Substrate 40 may be a single crystal silicon wafer containing a relatively light concentration of a dopant providing p-type conductivity. For example, substrate 40 may be lightly doped with 5×10¹⁵ cm⁻³ to 1×1¹⁷ cm⁻³ of boron by in situ doping during a CVD growth process forming the epitaxial layer.

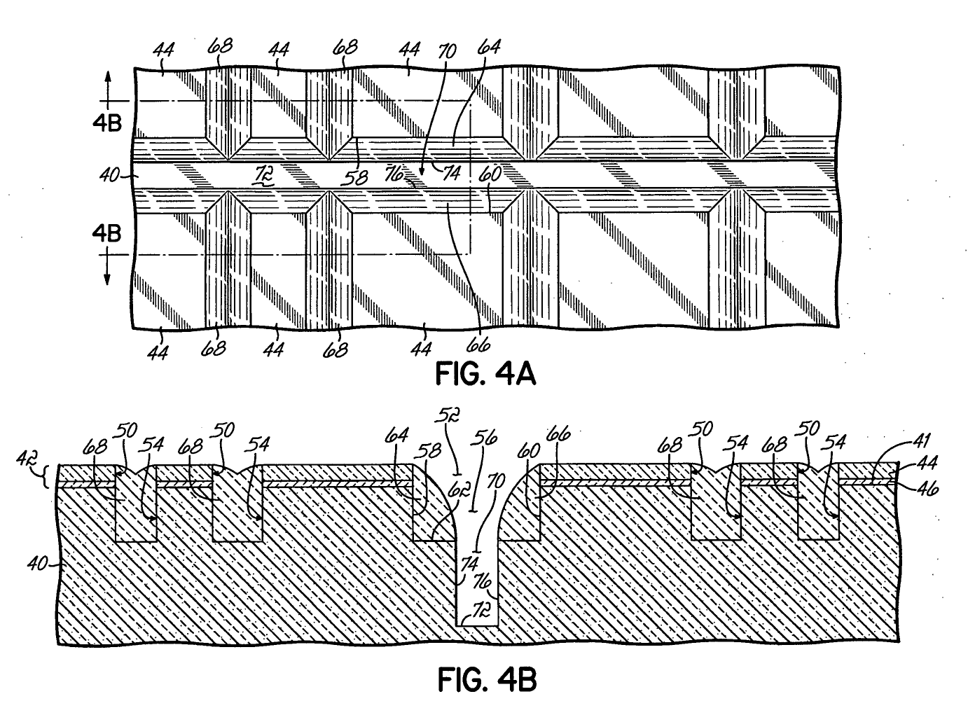

A pad structure 42, which includes a first pad layer 44 separated from the substrate 40 by a thinner second pad layer 46, is formed on a top surface 41 of the substrate 40. The second pad layer 46 may operate as a buffer layer to prevent any stresses in the constituent material of the first pad layer 44 from causing dislocations in the single crystal semiconductor material of substrate 40. The material(s) forming pad layers 44, 46 advantageously etch selectively to (i.e., with a significantly greater etch rate than) the constituent semiconductor material of substrate 40. The first pad layer 44 may be a conformal layer of nitride (Si₃N₄) formed by a thermal CVD process like low pressure chemical vapor deposition (LPCVD) or a plasma-assisted CVD process. The second pad layer 46 may be silicon oxide (SiO₂) grown by exposing substrate 40 to either a dry oxygen ambient or steam in a heated environment or, alternatively, deposited by a thermal CVD process. The pad structure 42 may further include an optional third pad layer (not shown) of, for example, oxide on a top surface of first pad layer 44, which may be advantageous during formation of the vertical trench extension 70 (FIGS. 4A,B).

A resist layer 48 is applied on pad layer 44 and subsequently exposed to a pattern of radiation effective to create a latent shallow trench pattern in the constituent material of the resist layer 48. The exposed resist of the resist layer 48 is subsequently developed to convert the latent shallow trench pattern into a plurality of relatively narrow openings 50 and a plurality of relatively wide openings, of which a single wide opening 52 is shown in FIG. 2, in the resist layer 48. The openings 50, 52 may be interconnected and continuous, as also shown in FIG. 2.

An anisotropic dry etching process, such as reactive-ion etching (RIE) or plasma etching, may then be used to transfer the shallow trench pattern from the patterned resist layer 48 into the pad layers 44, 46. The etching process, which may be conducted in a single etching step or multiple etching steps with different etch chemistries, removes portions of the pad structure 42 exposed through openings 50, 52 in the patterned resist layer 48 and stops vertically on the substrate 40. After etching is concluded, the resist layer 48 is stripped from the pad structure 42 by, for example, plasma ashing or exposure to a chemical stripper.

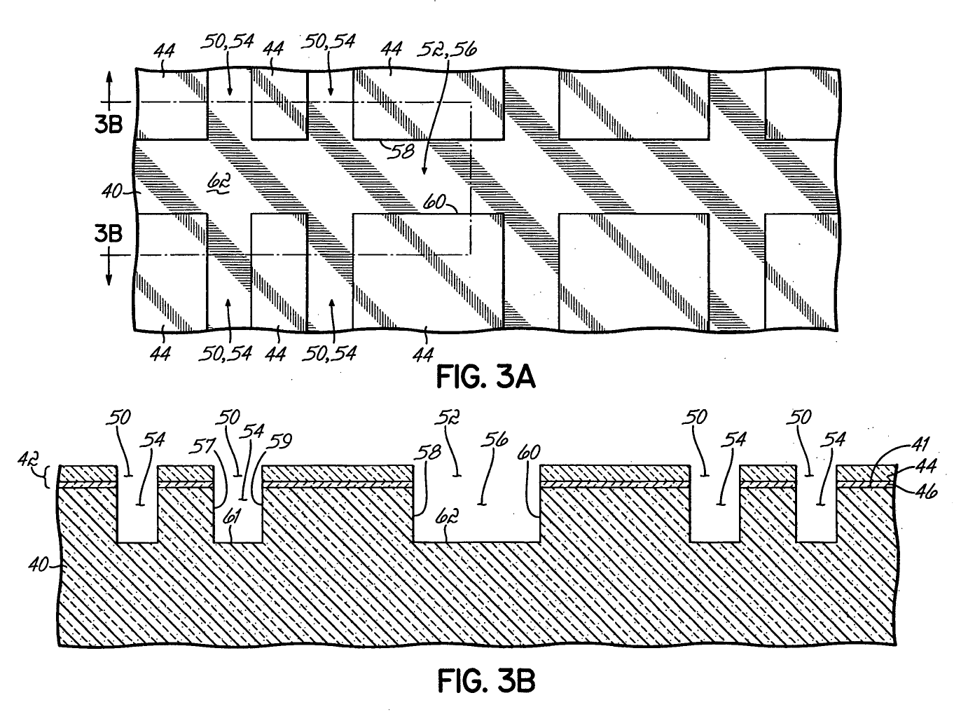

With reference to FIGS. 3A,B in which like reference numerals refer to like features in FIGS. 2A,B and at a subsequent fabrication stage, a plurality of relatively narrow shallow trenches 54 and a wide shallow trench 56 are defined in the semiconductor material of substrate 40 by an anisotropic dry etching process. Shallow trenches 54 coincide with the location of the relatively narrow openings 50 (FIGS. 2A,B) of the shallow trench pattern in pad structure 42 and shallow trench 56 coincides with the location of the relatively wide opening 52 (FIGS. 2A,B) of the shallow trench pattern in pad structure 42. The anisotropic dry etching process may be constituted by, for example, RIE, ion beam etching, or plasma etching using an etch chemistry (e.g., a standard silicon RIE process) that removes the constituent semiconductor material of substrate 40 selective to the materials constituting the pad layers 44, 46. Additional wide shallow trenches (not shown), each similar to wide shallow trench 56, are defined in the semiconductor material of substrate 40 by the anisotropic dry etching process forming shallow trench 56.

Opposite sidewalls 58, 60 of shallow trench 56 are substantially mutually parallel and oriented substantially perpendicular to the top surface 41 of substrate 40. The sidewalls 58, 60 extend vertically into the semiconductor material of substrate 40 to a bottom surface or base 62. Each of the shallow trenches 54 also includes opposite sidewalls 57, 59 that are substantially mutually parallel and oriented substantially perpendicular to the top surface 41 of substrate 40. The sidewalls 57, 59 extend vertically into the semiconductor material of substrate 40 and a bottom surface or base 61 connects the sidewalls 57, 59. At this fabrication stage of the processing method, the depths of base 61 and base 62 are approximately equal.

With reference to FIGS. 4A,B in which like reference numerals refer to like features in FIGS. 3A,B and at a subsequent fabrication stage, spacers 64, 66 are formed, respectively, on the sidewalls 58, 60 of shallow trench 56 that extend from the top surface 41 of substrate 40 to base 62. Spacers 64, 66 may be formed by depositing a conformal layer (not shown) of a dielectric material, such as silicon oxide deposited by a CVD process, and anisotropically etched using a RIE or plasma etching process to remove the dielectric material primarily from horizontal surfaces selective to the constituent semiconductor material of substrate 40.

The spacers 64, 66 narrow, but do not completely occlude, the shallow trench 56 such that a portion of the base 62 of shallow trench 56 is exposed between the spacers 64, 66. A person having ordinary skill will appreciate that additional shallow trenches (not shown), similar to shallow trench 56, defined in the substrate 40 will include spacers (not shown) similar to spacers 64, 66. The dielectric material of the conformal layer forming spacers 64, 66 in trench 56 also substantially fills each of the trenches 54 with an etch mask plug 68.

An anisotropic etching process is used to deepen shallow trench 56, and other shallow trenches similar to trench 56, to define a pigtail or vertical trench extension 70, also referred to as a deep trench. The anisotropic etching process removes the constituent semiconductor material of substrate 40 across the portion of base 62 exposed between the spacers 64, 66. The vertical trench extension 70 has a bottom surface or base 72 and sidewalls 74, 76 disposed between base 72 and base 62 of shallow trench 56. Spacer 64 is separated from spacer 66 by a gap that, near base 62, is approximately equal to a width between the vertical sidewalls 74, 76 of the vertical trench extension 70. The pad structure 42 and the spacers 64, 66 operate as an etch mask for semiconductor material in the covered regions across the top surface 41 of substrate 40. The absolute depths to which the shallow trench 56 and vertical trench extension 70 are etched may vary with particular device designs. A person having ordinary skill will appreciate that additional shallow trenches (not shown), similar to shallow trench 56, defined in the semiconductor material of substrate 40 will include a vertical trench extension similar to vertical trench extension 70. Shallow trenches 54 are each masked by a corresponding one of the etch mask plugs 68 and, hence, are unaffected by the anisotropic etching process forming vertical trench extension 70. It follows that the shallow trenches 54 are not deepened when the vertical trench extension 70 is formed.

Spacer 64 has a width measured in the horizontal plane near the base 62 as a distance between the sidewall 58 and the remote edge or corner of the spacer 64 proximate to the base 62. Spacer 66 has a width measured in the horizontal plane near the base 62 as a distance between the sidewall 60 and the remote edge or corner of the spacer 66 proximate to the base 62. Spacer 64 and spacer 66 have approximately equal widths. In contrast, the widths of the trenches 54 are not required to be identical. The width of the widest trench 54, which is measured horizontally between sidewalls 57, 59 (FIG. 3B), is less than two times the width of spacer 64 or two times the width of spacer 66. The width of trench 56, which is measured horizontally between sidewalls 58, 60, is two times the width of spacer 64 (or spacer 66) plus the width of the vertical trench extension 70, which is measured as a horizontal distance between sidewalls 74, 76.

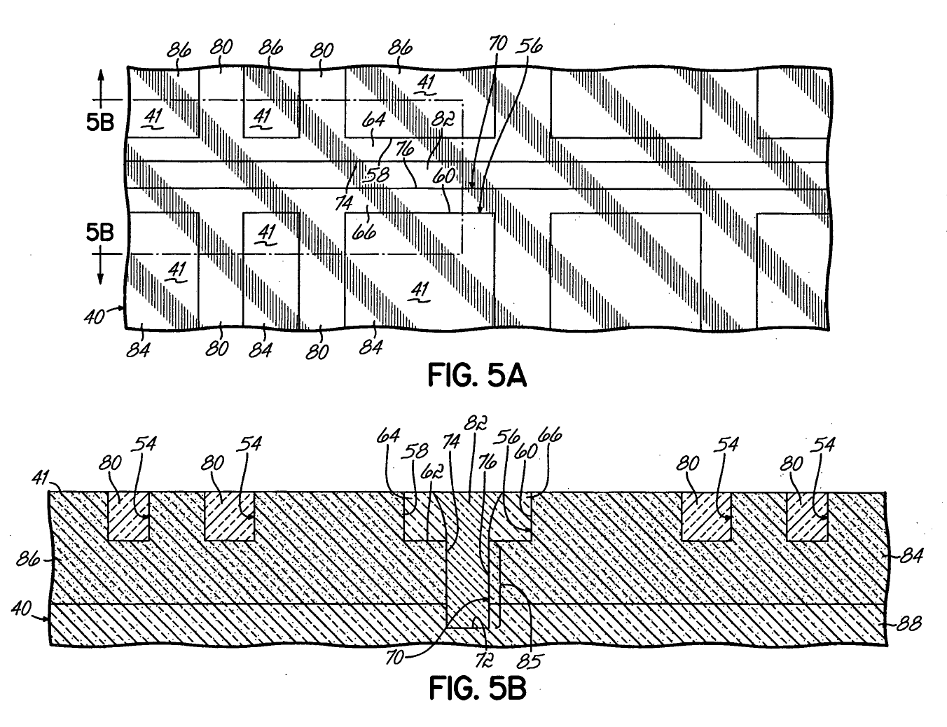

With reference to FIGS. 5A,B in which like reference numerals refer to like features in FIGS. 4A,B and at a subsequent fabrication stage, the contiguous open space of the shallow trench 56 and the vertical trench extension 70 are filled with an insulating or dielectric material, which may advantageously be the same material as constituting spacers 64, 66. The dielectric material may be CVD oxide, a high-density plasma (HDP) oxide, or tetraethylorthosilicate (TEOS). Any overfill of dielectric material may be removed by planarizing to the top surface of the pad structure 42 with, for example, a chemical-mechanical polishing (CMP) process. A high temperature process step may be used to densify a TEOS fill. The top surface 41 of substrate 40 is then exposed by removing pad structure 42 using a suitable process and another CMP process follows to planarize the top surface 41.

After planarization, the residual material of the etch mask plug 68 (FIGS. 4A,B) in each of the shallow trenches 54 defines one of a plurality of shallow trench isolation (STI) regions 80. The dielectric material in the shallow trench 56 and the vertical trench extension 70 and the spacers 64, 66, which merge together if formed of the same dielectric material as shown in FIGS. 5A,B, collectively constitute an STI region 82. A vertical extension portion 85 of the STI region 82 is located in the vertical trench extension 70 and is positioned vertically relative to the top surface 41 at a depth greater than the depth of base 62 and vertically between the depths of bases 62 and 72. The extension portion 85 extends to a greater depth than any of the other STI regions 80, which each have a base at approximately the same depth as base 62. In one embodiment, the depth of base 62 is about 0.4 μm and the depth of base 72 is about 1 μm. The vertical trench extension 70 may only be partially filled with dielectric material during the filling process. Accordingly, the extension portion 85 may include air- or gas-filled voids.

Advantageously, the vertical extension portion 85 of the STI region 82 is formed without the use of a distinct patterned resist and additional lithography. Instead, the spacers 64, 66 beneficially define an etch mask for forming the vertical trench extension 70 in a self-aligned manner with the shallow trench 56. The material constituting spacers 64, 66 also fill the other shallow trenches 54 so that the depth of trenches 54 is not increased by the process forming the vertical trench extension 70.

The substrate 40 is subsequently selectively doped to form a dual-well structure consisting of an N-well 84 and a P-well 86. The N-well 84, as well as other N-wells (not shown) dispersed across the substrate 40, are formed by patterning a blocking layer (not shown) applied on the top surface 41 with techniques known in the art and implanting an appropriate n-conductivity type impurity into the substrate 40 in unmasked regions. The P-well 86, as well as other P-wells (not shown) dispersed across the substrate 40, are likewise formed by patterning another blocking layer (not shown) applied on top surface 41 and implanting an appropriate p-conductivity type impurity into the substrate 40 in this set of unmasked regions. Generally, the dopant concentration in the N-well 84 ranges from about 5.0×10¹⁷ cm⁻³ to about 7.0×10¹⁸ cm⁻³ and the dopant concentration in the P-well 86 ranges from about 5.0×10¹⁷ cm⁻³ to about 7.0×10¹⁸ cm⁻³. A thermal anneal maybe required to electrically activate the implanted impurities operating as the p-type and n-type dopants.

The present invention is tolerant of inaccuracies in the masking and implantation process used to form the N- and P-wells 84, 86. Specifically, the extension portion 85 of the STI region 82 is located at the junction between the N-well 84 and the P-well 86. The sidewalls 74, 76 of vertical trench extension 70 are located between the N-well 84 and the P-well 86 and the base 72 extends to a greater depth into the semiconductor material of the substrate 40 than the deepest doped depth of the N-well 84 and the P-well 86 in the semiconductor material of the substrate 40. Vertical extension 70 is formed substantially centrally (i.e., self-aligned) relative to the sidewalls 58, 60 of shallow trench 56 because the spacers 64, 66 advantageously provide an etch mask. If a conventional lithographic mask were used to form vertical extension 70, then misalignment of the mask overlay could effect the location of vertical extension 70. Advantageously, the width of the extension portion 85 may be minimized in the device design.

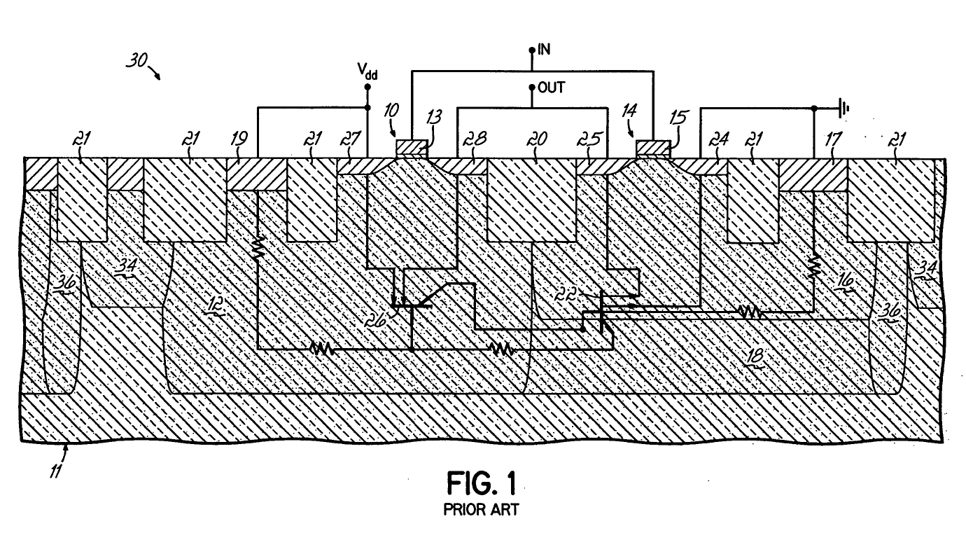

The present invention may be advantageously implemented in a triple-well structure further including a deep buried N-well or N-band (not shown) in the substrate 40 that supplies electrical isolation for the P-well 86. The P-well 86 is arranged between the N-band 18 (FIG. 1) and the top surface 41 of substrate 40. The N-band 18, as well as other N-bands (not shown) dispersed across the substrate 40, are formed by patterning a blocking layer (not shown), such as a photoresist, applied on the top surface 41 and implanting an appropriate n-conductivity type impurity into the substrate 40 in this set of unmasked regions. Generally, the dopant concentration in the N-band ranges from about 5.0×10¹⁷ cm⁻³ to about 7.0×10¹⁸ cm⁻³. In this instance, the base 72 of vertical extension 70 is limited to a depth at which the sidewalls 74, 76 fail to extend completely through the N-band 18, which maintains the continuity between the N-well 84 and N-band 18.

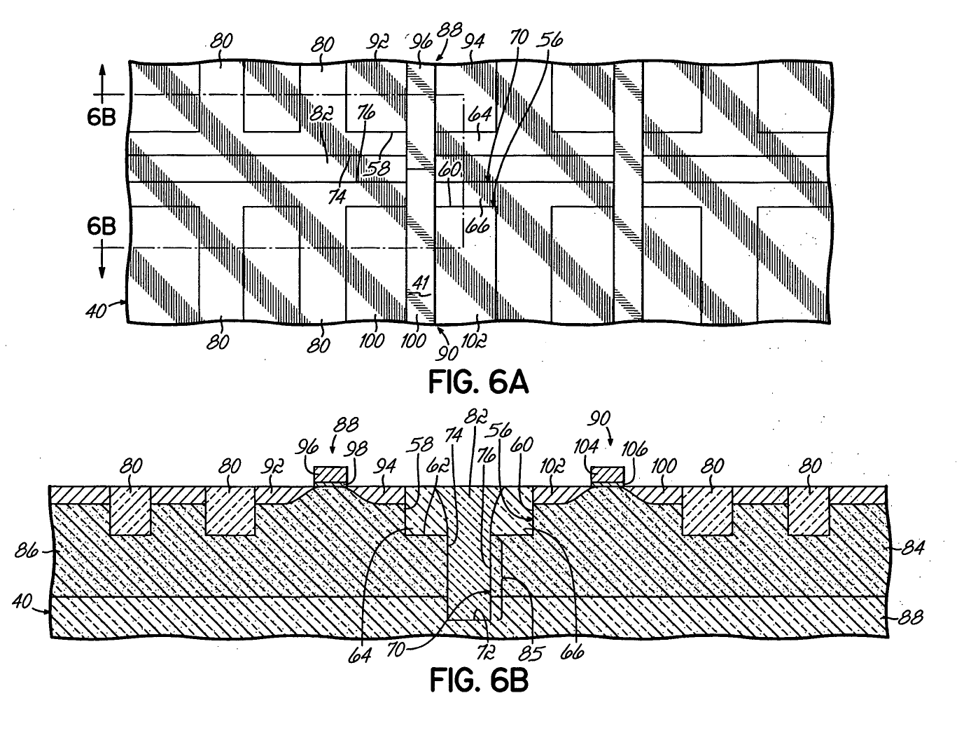

With reference to FIGS. 6A,B in which like reference numerals refer to like features in FIGS. 5A,B and at a subsequent fabrication stage, standard bulk CMOS processing follows the formation of the dual-well structure. To define a bulk CMOS device, an N-channel transistor 88 is built using the P-well 86 and a P-channel transistor 90 is built using the N-well 84. The N-channel transistor 88 includes n-type diffusions in the semiconductor material of substrate 40 representing a source region 92 and a drain region 94 that flank opposite sides of a channel region in the semiconductor material of substrate 40, a gate electrode 96 overlying the channel region, and a gate dielectric 98 electrically isolating the gate electrode 96 from the substrate 40. Similarly, the P-channel transistor 90 includes p-type diffusions in the semiconductor material of substrate 40 representing a source region 100 and a drain region 102 that flank opposite sides of a channel region in the semiconductor material of substrate 40, a gate electrode 104 overlying the channel region, and a gate dielectric 106 electrically isolating the gate electrode 104 from the substrate 40. Other structures, such as sidewall spacers (not shown), may be included in the construction of the N-channel transistor 88 and the P-channel transistor 90.

The source and drain regions 92, 94 and the source and drain regions 100, 102 may be formed in the semiconductor material of substrate 40 by ion implantation of a suitable dopant species having an appropriate conductivity type. The conductor used to form the gate electrodes 96, 104 may be, for example, polysilicon, silicide, metal, or any other appropriate material deposited by a CVD process, etc. The gate dielectrics 98, 106 may comprise any suitable dielectric or insulating material like silicon dioxide, silicon oxynitride, a high-k dielectric, or combinations of these dielectrics. The dielectric material constituting dielectrics 98, 106 may be between about 1 nm and about 10 nm thick, and may be formed by thermal reaction of the semiconductor material of the substrate 40 with a reactant, a CVD process, a physical vapor deposition (PVD) technique, or a combination thereof.

Processing continues to complete the semiconductor structure, including but not limited to forming electrical contacts (not shown) to the gate electrodes 96, 104, source region 92, drain region 94, source region 100, and drain region 102. The contacts may be formed using any suitable technique, such as a damascene process in which an insulator is deposited and patterned to open vias, and then the vias are filled with a suitable conductive material, as understood by a person having ordinary skill in the art. The N-channel and P-channel transistors 88, 90 are coupled using the contacts with other devices on substrate 40 and peripheral devices with a multilevel interconnect structure consisting of conductive wiring and interlevel dielectrics (not shown). The N-well 84 is electrically coupled with the standard power supply voltage (V_{dd}) and the P-well 86 is electrically coupled with the substrate ground potential.

In accordance with the principles of the invention, the extension portion 85 of the STI region 82 operates to elevate the holding voltage of the N-channel and P-channel transistors 88, 90 for increasing the resistance of the bulk CMOS device to latch-up. Because the base 62 of the vertical trench extension 70 is deeper than the deepest boundary of the N-well 84, holes emitted from the source region 92 of the P-channel transistor 88 are directed to the semiconductor material of substrate 40 flanking extension portion 85. The holes rapidly recombine with electrons in the substrate 40, which reduces or eliminates the gain of the lateral parasitic PNP structure 26 (FIG. 1) because a negligible hole current is collected by the P-well 86 and, thereby, suppresses latch-up.

The vertical trench extension 70 is defined in the semiconductor material of the substrate 40 in a maskless manner without the implementation of a lithographic mask (or recticle) and a lithography process to provide a patterned resist layer as a preparatory step to the anisotropic etching process used to define the vertical trench extension 70. As used herein, a mask or reticle is any device, such as a photomask, having a pattern of transparent and opaque areas that allow selective irradiation of a resist layer on a substrate surface. Instead of the absent patterned resist layer, the spacers 64, 66 are advantageously used as an etch mask for forming the vertical trench extension 70.

References herein to terms such as “vertical”, “horizontal”, etc. are made by way of example, and not by way of limitation, to establish a frame of reference. The term “horizontal” as used herein is defined as a plane parallel to the top surface 41 of substrate 40, regardless of its actual spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The fabrication of the semiconductor structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the present invention. It is also understood that features of the present invention are not necessarily shown to scale in the drawings.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A method of fabricating a semiconductor structure in a substrate of a semiconductor material, the method comprising:
forming a trench in the semiconductor material of the substrate with first sidewalls extending between a base of the trench and a top surface of the substrate; and
masklessly etching the semiconductor material of the substrate to deepen the trench by defining a vertical trench extension with second sidewalls that extend from the base into the substrate and that are narrowed relative to the first sidewalls.

2. The method of claim 1 further comprising:
forming a first doped well in the semiconductor material of the substrate; and
forming a second doped well in the semiconductor material of the substrate proximate to the first doped well such that the second sidewalls of the trench are positioned between the first and second doped wells.

3. The method of claim 2 further comprising:
forming first and second diffusions of a first conductivity type in the first doped well to define source and drain regions of a first transistor; and
forming first and second diffusions of a second conductivity type in the second doped well to define source and drain regions of a second transistor.

4. The method of claim 1 wherein the spacers on the first sidewalls of the trench self-align the second sidewalls of the vertical trench extension relative to the first sidewalls of the trench.

5. The method of claim 1 wherein forming the spacers further comprises:
depositing a conformal layer of a dielectric material on the sidewalls and the base of the trench; and
anisotropically etching the dielectric material of the conformal layer to define the spacers.

6. The method of claim 1 wherein forming the spacers further comprises:
depositing a conformal layer of silicon oxide by a chemical vapor deposition process on the sidewalls and the base of the trench; and
anisotropically etching the silicon oxide of the conformal layer to define the spacers.

7. The method of claim 6 further comprising:
filling the vertical trench extension and the trench with silicon oxide.

8. The method of claim 1 further comprising:
filling the vertical trench extension and the trench with a dielectric material.

9. A method of fabricating a semiconductor structure in a substrate of a semiconductor material, the method comprising:
forming a first trench in the semiconductor material of the substrate with first sidewalls extending between a first base of the first trench and a top surface of the substrate;
forming a second trench in the semiconductor material of the substrate with second sidewalls and extending between a second base of the second trench and the top surface of the substrate;
forming spacers of a dielectric material in the first trench that are separated by a gap so as to partially expose the first base; and
filling the second trench with the dielectric material to completely cover the second base concurrently with forming the spacers.

10. The method of claim 9 further comprising:
anisotropically etching the semiconductor material between the spacers to extend a depth of the first trench into the substrate.

11. The method of claim 10 further comprising:
forming a first doped well in the semiconductor material of the substrate; and
forming a second doped well in the semiconductor material of the substrate proximate to the first doped well such that the second sidewalls of the trench are positioned between the first and second doped wells.

12. The method of claim 11 further comprising:
forming first and second diffusions of a first conductivity type in the first doped well to define source and drain regions of a first transistor; and
forming first and second diffusions of a second conductivity type in the second doped well to define source and drain regions of a second transistor.

13. The method of claim 9 wherein forming the spacers further comprises:
depositing a conformal layer of a dielectric material on the sidewalls and the base of the trench; and
anisotropically etching the dielectric material of the conformal layer to define the spacers.

14. The method of claim 9 wherein forming the spacers further comprising:
depositing a conformal layer of silicon oxide by a chemical vapor deposition process on the sidewalls and the base of the trench; and
anisotropically etching the silicon oxide of the conformal layer to define the spacers.

15. The method of claim 14 further comprising:
filling the deepened trench with silicon oxide.

16. The method of claim 9 further comprising:
filling the deepened trench with a dielectric material.

17. A semiconductor structure comprising:
a substrate of a semiconductor material having a top surface;
a first trench defined in the semiconductor material of the substrate, the first trench including a base and sidewalls extending from the base toward the top surface;
spacers of a dielectric material positioned on the first sidewalls of the first trench and separated from each other by a gap to partially expose the base of the first trench; and
a vertical trench extension having sidewalls extending from the base of the first trench away from the top surface into the semiconductor material of the substrate, the sidewalls of the vertical trench being substantially aligned with the gap separating the spacers.

18. The semiconductor structure of claim 17 further comprising:
a first doped well formed in the semiconductor material of the substrate; and
a second doped well formed in the semiconductor material of the substrate and disposed adjacent to the first doped well, the sidewalls of the first trench being positioned between the first and second doped wells.

19. The semiconductor structure of claim 18 further comprising:
first and second diffusions of a first conductivity type in the first doped well to define source and drain regions of a first transistor; and
first and second diffusions of a second conductivity type in the second doped well to define source and drain regions of a second transistor.

20. The semiconductor structure of claim 19 further comprising:
a first gate electrode electrically isolated from the substrate and positioned between the first and second diffusions of the first conductivity type; and
a second gate electrode electrically isolated from the substrate and positioned between the first and second diffusions of the second conductivity type.

21. The semiconductor structure of claim 17 further comprising:
an amount of the dielectric material filling the vertical trench extension and the gap between the spacers.

22. The semiconductor structure of claim 17 further comprising:
a second trench defined in the semiconductor material of the substrate, the second trench including a base and sidewalls extending from the base of the second trench toward the top surface.

23. The semiconductor structure of claim 22 wherein the first trench has a first trench width measured between the sidewalls of the first trench, the spacers each have a spacer width measured from a corresponding one of the first sidewalls, and the second trench having a second trench width measured between the sidewalls of the second trench that is less than two times the spacer width.
